(19) United States
(12) Patent Application Publication
(10) Pub. No.: US 2026/0165172 A1
(43) Pub. Date: Jun. 11, 2026

(54) BOTTOM-UP THROUGH GLASS VIA PLATING WITH COATED LIQUID ADHESIVE ON GLASS SUBSTRATE

(71) Applicant: Intel Corporation, Santa Clara, CA (US)

(72) Inventors: Wendy Lin, Chandler, AZ (US); Shuqi Lai, Phoenix, AZ (US); Vincent Eze, Chandler, AZ (US); Aaditya Candadai, Chandler, AZ (US); Yi Cao, Chandler, AZ (US); Whitney Bryks, Tempe, AZ (US); Son Nguyen, Gilbert, AZ (US); David Vickery, Gilbert, AZ (US); Dilan Seneviratne, Phoenix, AZ (US); Lei Jin, Chandler, AZ (US); Richard Surmaitis, Scottsdale, AZ (US); Srinivas Pietambaram, Chandler, AZ (US); Anastasia Arrington, Queen Creek, AZ (US)

(73) Assignee: Intel Corporation, Santa Clara, CA (US)

(21) Appl. No.: 18/977,423

(22) Filed: Dec. 11, 2024

(51) Int. Cl. H01L 23/498; H01L 21/48; H01L 23/15; H01L 25/065

(52) U.S. Cl. CPC H10W 70/685; H10W 70/05; H10W 70/095; H10W 70/65; H10W 70/69; H10W 70/692; H10W 90/00

(57) ABSTRACT

Bottom-up plated through glass vias, and related packages, apparatuses, systems, and methods of fabrication are discussed. A glass substrate of a package has a first surface, an opposing second surface, and an opening extending between the first and second surfaces. A polymeric material is within the opening and on a first portion of a sidewall of the glass substrate defined by the opening. A via metallization is also within the opening and extends from the first surface to the second surface such that the polymeric material is between a portion of the via metallization and the sidewall and another portion of the via metallization is immediately adjacent the sidewall.

### BACKGROUND

Higher performance, lower cost, increased miniaturization, greater packaging density, and increased product flexibility of integrated circuit (IC) devices are ongoing goals of the electronics industry. IC packaging is a stage of semiconductor or IC device fabrication in which an IC that has been monolithically fabricated on a chip (or die) is assembled into a package that protects the IC chip from physical damage and communicatively connects the IC to other packaged IC chips and/or a scaled host component, such as a package substrate, or a printed circuit board. Multiple chips can be co-assembled, for example, into a multi-die package. Some package architectures include an IC die attached to a glass substrate and coupled to electrically conductive through-glass vias (TGVs) extending through the glass substrate. Glass substrates have advantages such as low dielectric loss, high thermal stability, and improved surface planarity and surface quality. However, glass core failures such as cracks are observed due to high stress in the TGV from copper seed/glass interface during thermal processing. It is with respect to these and other considerations that the present improvements have been needed. Such improvements may become critical as the desire to deploy high-performance IC packages in various devices and systems becomes more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram illustrating example methods for fabricating and assembling glass substrate structures having bottom-up plated through glass vias;

FIGS. 2, 3, 4, 5, 6, 7, 8, 9, 10, 11 and 12 are illustrations of cross-sectional side views of glass substrate structures as the methods of FIG. 1 are practiced to form bottom-up plated through glass vias;

FIGS. 13, 14, and 15 are illustrations of cross-sectional side views of package structures as the methods of FIG. 1 are practiced to assemble a package assembly having a glass substrate with bottom-up plated through glass vias;

FIG. 16 illustrates exemplary systems employing an IC assembly including a glass core substrate with bottom-up plated through glass vias; and

FIG. 17 is a block diagram of a computing device, all arranged in accordance with at least some implementations of the present disclosure.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. Herein, the term “predominantly” indicates not less than 50% of a particular material or component while the term “substantially pure” indicates not less than 99% of the particular material or component and the term “pure” indicates not less than 99.9% of the particular material or component. Unless otherwise indicated, such material percentages are based on atomic percentage. Herein the term concentration is used interchangeably with material percentage and also indicates atomic percentage unless otherwise indicated.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direction contact. Furthermore, the terms “substantially,” “close,” “approximately,” “near,” and “about,” generally refer to being within +/-10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Apparatuses, systems, and methods are described herein related to bottom-up plating of through glass vias within openings of a glass core substrate using a foil adhered to a liquid adhesive formed on a surface of the glass core substrate such that the liquid adhesive leaves the openings exposed for plating.

As described above, current package architectures may include one or more IC dies attached to a glass substrate and coupled to electrically conductive through-glass vias (TGVs) extending through the glass substrate. However, current fabrication techniques have difficulties including glass core failures due to high mechanical stresses at the copper seed/glass interface during thermal processing, and other reliability issues. In particular, the high coefficient of thermal expansion (CTE) mismatch between the via metallization and the glass core cause difficulties when typical copper seed and plating techniques are used. Embodiments discussed herein enable the use of bottom-up plating such as bottom-up copper plating to at least partially decouple the TGV from the sidewall of the glass substrate by not having a seed layer directly deposited on the sidewall. Thereby, the CTE mismatch between the via metallization and the glass is mitigated and the stress therebetween is reduced. This, in turn, reduces failures such as glass core substrate cracks.

Notably, the via metallization within the openings of the glass core is absent a seed layer, which can be a different material than the bulk (e.g., a titanium-copper seed layer for a bulk copper) or a different microstructure (e.g., a seed layer having a different grain size than the bulk metal). In some embodiments, an entirety of the via metallization disclosed herein is a substantially pure (99%+) or pure (99.9%+) metal such as substantially pure or pure copper having a constant microstructure throughout. As used herein, the term microstructure indicates the microscopic structure of the material and refers to the arrangement of the materials constituents such as grains, defects, grain boundaries, etc. The term constant throughout is used to indicate each portion of the material has the same or similar microstructure in each of the regions. In some embodiments, the via metallization is physically decoupled at least partially (e.g., at some positions) from the sidewall of the opening within the glass such that an air gap is evident between the via metallization and the sidewall. The term air gap indicates a gap that is filled with any pertinent ambient gas. The ambient gas may be present during the formation of the gap (i.e., if the air gap is pinched off) or the ambient gas may be provided at any subsequent time. Notably, the term air gap does not necessarily indicate a gap filled with atmospheric air but instead indicates a gap filled with ambient gas, in accordance with its use in the art.

In some embodiments, the via metallization is formed by coating a thin liquid adhesive such as a polymeric liquid on a glass substrate, such that the liquid adhesive covers a planar surface of the glass substrate but does not bridge over or clog openings extending through the glass substrate. A foil such as a copper foil is bonded to the liquid adhesive and the TGVs are bottom-up plated from the copper foil, which is ultimately removed. The discussed glass substrates and techniques inclusive of bottom-up plated TGVs provide a variety of advantages including reduced stress, as discussed, not clogging the openings for improved performance to enable high aspect ratio TGVs, and mitigating risk of plating voids in high aspect ratio TGVs. For example, conventional seed plating approaches start plating from all surfaces with a seed layer, which has the risk of closing up from sidewall first, leaving a void within the opening.

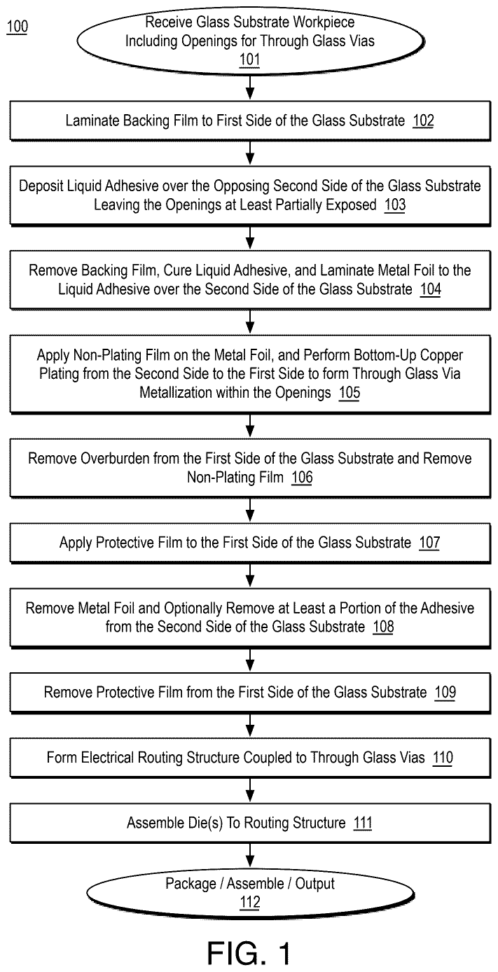

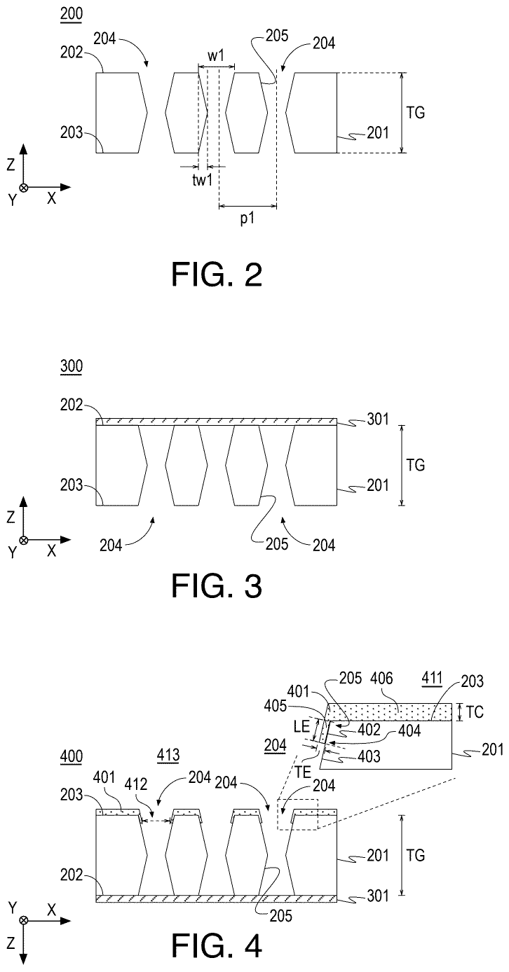

FIG. 1 is a flow diagram illustrating example methods 100 for fabricating and assembling glass substrate structures having bottom-up plated through glass vias, arranged in accordance with at least some implementations of the present disclosure. For example, methods 100 may be implemented to fabricate any glass substrates structures, package structures, or assemblies discussed herein. In the illustrated embodiment, methods 100 include one or more operations as illustrated by operations 101-112. However, embodiments herein may include additional operations, certain operations being omitted, or operations being performed out of the order provided. FIGS. 2-15 illustrate structures and components as methods 100 are practiced.

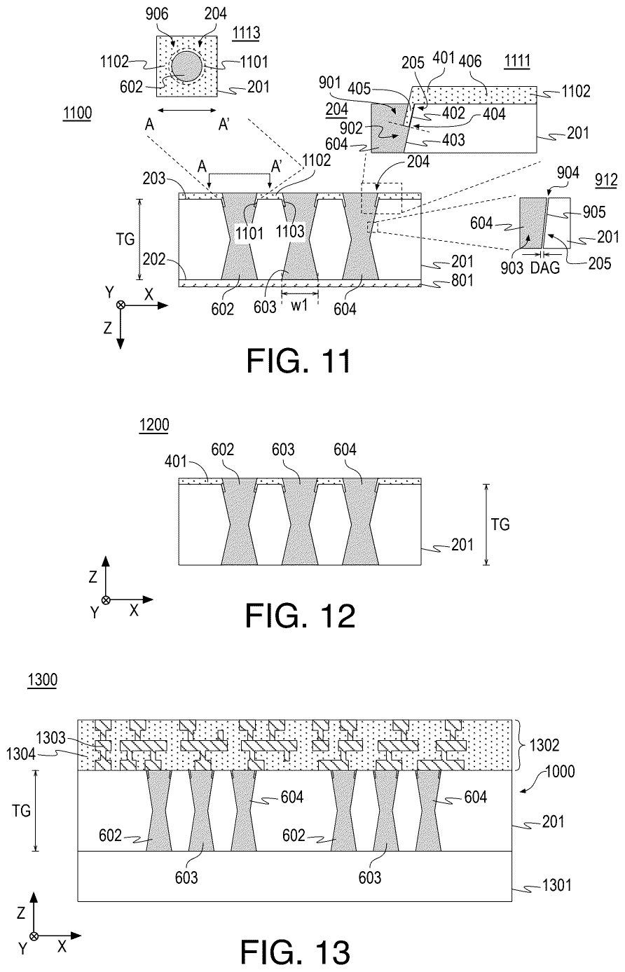

FIGS. 2, 3, 4, 5, 6, 7, 8, 9, 10, 11 and 12 are illustrations of cross-sectional side views of glass substrate structures as methods 100 are practiced to form bottom-up plated through glass vias, arranged in accordance with at least some implementations of the present disclosure. FIGS. 9 and 11 further include top-down views of features of bottom-up plated through glass vias, arranged in accordance with at least some implementations of the present disclosure. FIGS. 13, 14, and 15 are illustrations of cross-sectional side views of package structures as methods 100 are practiced to assemble a package assembly having a glass substrate with bottom-up plated through glass vias, arranged in accordance with at least some implementations of the present disclosure. Methods 100 provides a process flow for bottom-up plating of TGVs by coating a liquid adhesive on a glass substrate such that openings within the glass substrate are left open to bottom-up plating from a metal foil attached to the adhesive.

Methods 100 begins at operation 101, where a workpiece such as a glass substrate including a thickness of glass and any number of holes or openings extending through the thickness of the glass is received. The workpiece may be prepared upstream of methods 100 and may be in a large panel format, a wafer format, or the like. In addition to the thickness of glass, the workpiece received at operation 101 may include one or more materials upon which electrical routing structures may be formed.

FIG. 2 is an illustration of a cross-sectional side view of a glass substrate structure 200 including materials received for processing such as a glass substrate 201 having a first surface 202, an opposing second surface 203, and a thickness TG extending between first surface 202 and second surface 203, and orthogonal to both. IC device package structures may be advantageously fabricated upon glass substrate 201 as flatness and/or thickness control for a preform of glass is superior to that of starting substrates based on organic materials (e.g., epoxy), and costs can be significantly lower than for monocrystalline materials (e.g., silicon).

Glass substrate 201 is a solid bulk material layer that may have been previously formed into any shape in plan view (e.g., x-y plane) suitable for a packaging workpiece, such as a rectangular shape. Glass substrate 201 has a thickness TG that may vary with implementation, for example, to limit warpage while remaining thin enough to permit the formation of through glass vias. In some embodiments, thickness TG is not less than 200 μm and not more than 2000 μm. In some embodiments, thickness TG is advantageously not less than 350 μm and not more than 500 μm such as a thickness of 400 μm.

In some embodiments, glass substrate 201 is predominantly silicon and oxygen. In some embodiments, glass substrate 201 includes at least 23 percent silicon and at least 26 percent oxygen, by weight (i.e., wt. %). Glass substrate 201 may further include one or more additives, such as, Aluminum, Boron, Magnesium, Calcium, Barium, Tin, Sodium, Potassium, Strontium, Phosphorus, Zirconium, Lithium, Titanium, or Zinc. In embodiments where glass substrate 201 includes at least 23 wt. % Si and at least 26 wt. % O, glass substrate 201 may further include at least 5 wt. % Al. Additives within glass substrate 201 may form suboxides (A₂O) monoxides (AO), binary oxides (AO₂), ternary oxides (ABO₃), and mixtures thereof. For example, glass substrate 201 may include AlOₓ (e.g., Al₂O₃), BOₓ (e.g., B₂O₃), MgOₓ (e.g., MgO), CaOₓ (e.g., CaO), SrOₓ (e.g., SrO), BaOₓ (e.g., BaO), SnOₓ (e.g., SnO₂), NaOₓ (e.g., Na₂O), KOₓ (e.g., K₂O), POₓ(e.g., P₂O₃), ZrOₓ (e.g., ZrO₂), LiOₓ (e.g., Li₂O), TiOₓ (e.g., TiO₂), or ZnOₓ (e.g., ZnO₂). In some embodiments, glass substrate is a BF33 glass. Depending on chemical composition, glass substrate 201 may therefore be referred to as silica, fused silica, aluminosilicate, borosilicate, or alumino-borosilicate, for example.

In some embodiments, glass substrate 201 is advantageously a bulk material of substantially homogeneous composition in contrast to a composite material that may merely include glass fillers and/or fibers. Although glass substrate 201 is substantially amorphous in some embodiments, glass substrate 201 may also have other morphology or microstructure, such as polycrystalline (e.g., nanocrystalline). In some embodiments, glass substrate 201 is rectangular in shape in plan view. However, other shapes may be used. In some embodiments, glass substrate 201 is a layer of glass having a thickness of not less than 50 μm, a first length of not less than 10 mm and a second length orthogonal to the first length of not less than 10 mm. In some embodiments, glass substrate 201 is absent any organic adhesive or other organic material. Although not depicted, one or more material layers may clad either or both of first surface 202 and second surface 203 of glass substrate 201 so that glass substrate 201 is a bulk or core layer of a multi-layered substrate. Exemplary cladding materials include inorganic materials such as silicon nitride (SiNₓ) or silicon oxynitride (SiOₓN_{y}). In other embodiments, a silicon layer (polycrystalline or monocrystalline) may clad one or both sides of glass substrate 201. Organic material layers, such as polymer dielectric materials, may also clad one or more sides of glass substrate 201. Hence, while glass substrate 201 is advantageously substantially free of organic materials (e.g., no adhesives, etc.), a workpiece may include organic materials within a substrate stack that includes glass substrate 201. Such claddings or build-up layers may be fabricated on glass substrate 201 as discussed herein below.

As shown, holes, through holes, or openings 204 in glass substrate 201 extend from first surface 202 to second surface 203 and through thickness TG of glass substrate 201. Furthermore, openings 204 define sidewalls 205 of glass substrate 201 that also extend from first surface 202 to second surface 203. Openings 204 may be formed using any suitable technique or techniques such as laser assisted etch techniques with a dual side etch (as shown) to form a dual taper profile or a single side etch which forms a single taper profile.

Openings 204 may have any suitable lateral cross-sectional shape in the x-y plane such as circular or oval (see FIGS. 9 and 11). Openings 204 have a diameter or cross-sectional width w1 (a longest distance across opening 204 in the x-y plane) and may have an optional taper defining a taper width tw1 and a corresponding taper angle. As used herein, taper width indicates a difference between an outer edge at maximum width w1 of opening 204 (i.e., at first surface 202 and/or second surface 203) and an outer edge of a minimum width (not shown) of opening 204. In the context of a dual taper opening 204, the minimum width is typically at the center of thickness TG of glass substrate 201 while in a single taper context, the minimum width is typically at the opposite one of first surface 202 and/or second surface 203 as the maximum width.

Openings 204 may have any suitable cross-sectional width w1 such as a width w1 in the range of about 15 to 105 μm, which may depend on the thickness TG of glass substrate 201. For example, thicker glass substrates 201 (e.g., TG of about 750 μm), width w1 may be in the range of about 95 to 105 μm. Taper width tw1 may be any suitable fraction of width w1 such as not more than 10% of width w1, not more than 20% of width w1, or not more than 30% of width w1. Furthermore, the thickness TG of glass substrate 201 over the width w1 of openings 204 defines an aspect ratio of openings 204. Notably, the techniques discussed herein enable the fill of higher aspect ratio openings 204. In some embodiments, the aspect ratio (AR=TG/w1) of openings 204 is not less than 5 (i.e., for a 400 μm thickness TG, opening widths w1 of not more than 80 μm). In some embodiments, the aspect ratio of openings 204 is not less than 10 (i.e., for a 400 μm thickness TG, opening widths w1 of not more than 40 μm). In some embodiments, the aspect ratio of openings 204 is not less than 20 (i.e., for a 400 μm thickness TG, opening widths w1 of not more than 20 μm). Other aspect ratio via metallizations may be used. It is noted that the discussed dimensions of openings 204 carry over to the resultant via metallizations formed within openings 204 and the via metallizations discussed herein below may have of the same dimensions, shapes, and characteristics.

Returning to FIG. 1, methods 100 continue at operation 102, where a backing film is laminated or otherwise attached to a first side of the glass substrate. The backing film may have any suitable composition and may be of any suitable thickness and rigidity such that the backing film seals a first side of the discussed openings of the glass substrate. Furthermore, the backing film may be attached to the glass substrate using any suitable technique or techniques such as a removable adhesive, a releasable tape, or the like.

FIG. 3 is an illustration of a cross-sectional side view of a glass substrate structure 300 similar to glass substrate structure 200 after attaching a backing film or material layer 301 that substantially covers first surface 202 and seals one side of each of openings 204 at first surface 202. Material layer 301 may be any material that provides a seal for openings 204 and is mechanically strong enough to withstand subsequent adhesive coating processing discussed herein below. In some embodiments, material layer 301 is a polymer material. As discussed, material layer 301 may be attached to first surface 202 using any suitable technique or techniques such as lamination techniques. In some embodiments, material layer 301 is releasable using, for example, a UV releasable film.

Returning to FIG. 1, methods 100 continue at operation 103, where a liquid adhesive is coated on the second surface opposite the backing film or material layer attached to the first surface at operation 102. Notably, the liquid adhesive is a material selected, and deposited at a particular thickness, such that it substantially coats the second surface but does not fully bridge over or clog the openings. For example, through liquid adhesive formulation modulation, coating parameter optimization (e.g., coating speed, dispense volume, vacuum pressure, and ramp down rate), a thin liquid adhesive can be formed on the planar area of the glass substrate without bridging or clogging the openings in the glass substrate.

FIG. 4 is an illustration of a cross-sectional side view of a glass substrate structure 400 similar to glass substrate structure 300 after deposition of polymeric or adhesive material 401 on second surface 203 of glass substrate 201 such that adhesive material 401 covers second surface 203 but leaves at least portions 412 of openings 204 exposed. Furthermore, a portion of adhesive material 401 extends into openings 204 such that a portion of adhesive material 401 is on a region or portion sidewall 205 while another region or portion of sidewall 205 is exposed.

As shown, adhesive material 401 is deposited over and on second surface 203 of glass substrate 201 such that glass substrate 201 includes openings 204 extending from first surface 202 to opposing second surface 203 with the application of adhesive material 401 leaving at least portions 412 of each of openings 204 exposed. Adhesive material 401 may be deposited using any suitable technique or techniques. In some embodiments, adhesive material 401 is deposited by a slit coating of a polymeric material. The polymeric material may be any suitable material that coats second surface 203, leaves portions 412 of each of openings 204 exposed, and provides sufficient adhesion to a subsequent metal foil. In some embodiments, adhesive material 401 is one of an epoxy material, a polyimide material, a benzocyclobutene based material, a polyethylene terephthalate based material, a high density polyethylene material or a polyethylene based material. Adhesive material 401 or portions thereof may remain in the resultant package formed using glass substrate 201 to provide additional adhesion properties for the resultant via metallization or other components and improved insulation.

As shown in enlarged view 411, adhesive material 401 is coated on second surface 203, to any suitable thickness TC (coating thickness). The portion of adhesive material 401 on second surface 203 may be characterized as a planar portion or top surface portion 406. Adhesive material 401 further has an extension 405 that extends a particular length LE (extension length) into openings 204 along sidewall 205. Within openings 204, adhesive material 401 may have the same thickness TC as top surface portion 406 or adhesive material 401 may have lesser thickness TE (extension thickness). As shown, extension 405 is on a region or portion 402 of sidewall 205 while region or portion 403 of sidewall 205 is exposed, such that portion 402 and region 403 meet at a boundary 404 therebetween.

The thickness TC of top surface portion 406 is orthogonal to second surface 203 (i.e., thickness TC is in the z-dimension) and may be any suitable value. In some embodiments, thickness TC of top surface portion 406 is not less than 2 μm and not more than 20 μm. In some embodiments, thickness TC of top surface portion 406 is not less than 5 μm and not more than 10 μm. In some embodiments, thickness TC of top surface portion 406 is not less than 2 μm and not more than 8 μm. In some embodiments, thickness TC of top surface portion 406 is not more than 5 μm. The thickness TE of extension 405 is orthogonal to sidewall 205 of opening 204 and may also be any suitable thickness. In some embodiments, thickness TE of extension 405 is not less than 0.5 μm and not more than 5 μm. In some embodiments, thickness TE of extension 405 is not less than 1 μm and not more than 3 μm. In some embodiments, thickness TE of extension 405 is not less than 0.5 μm and not more than 2 μm. In some embodiments, thickness TE of extension 405 is not less than 1 μm. The length LE of extension 405 is along sidewall 205 of opening 204 and may be of any suitable value. In some embodiments, length LE of extension 405 is not less than 5 μm and not more than 20 μm. In some embodiments, length LE of extension 405 is not less than 10 μm and not more than 15 μm. In some embodiments, length LE of extension 405 is not less than 5 μm and not more than 8 μm. In some embodiments, length LE of extension 405 is not less than 10 μm. Other thicknesses TC, TE and lengths LE may be used.

As discussed, the material of adhesive material 401 is selected, and deposited at a particular thickness and under selected conditions such that it substantially coats second surface 203 but does not fully bridge over or clog openings 204. In some embodiments, deposition of adhesive material 401 includes pulling a vacuum 413 on the workpiece (e.g., including second surface 203) while depositing adhesive material 401. In some embodiments, the deposition includes pulling vacuum 413 during slit coating. While not bound by theory, application of vacuum 413 may aid in leaving portions 412 of openings 204 such that adhesive material 401 is pulled toward second surface 203 and sidewall

Returning to FIG. 1, methods 100 continue at operation 104, where the backing film applied at operation 102 is removed, a metal foil is attached to the liquid adhesive applied at operation 103, and the liquid adhesive is cured. The liquid adhesive may be cured before or after metal foil lamination, depending on the material selected for the liquid adhesive. The backing film may be removed using any suitable technique or techniques such as UV release, peeling, or the like. The surface may be optionally cleaned after backing film removal. The metal foil may be attached to the liquid adhesive using any suitable technique or techniques such as roll on techniques, lamination techniques, or the like. In some embodiments, a cure step is administered after metal foil attachment, which may more securely bond the metal foil to the workpiece. In some embodiments, the cure is administered before metal foil bonding.

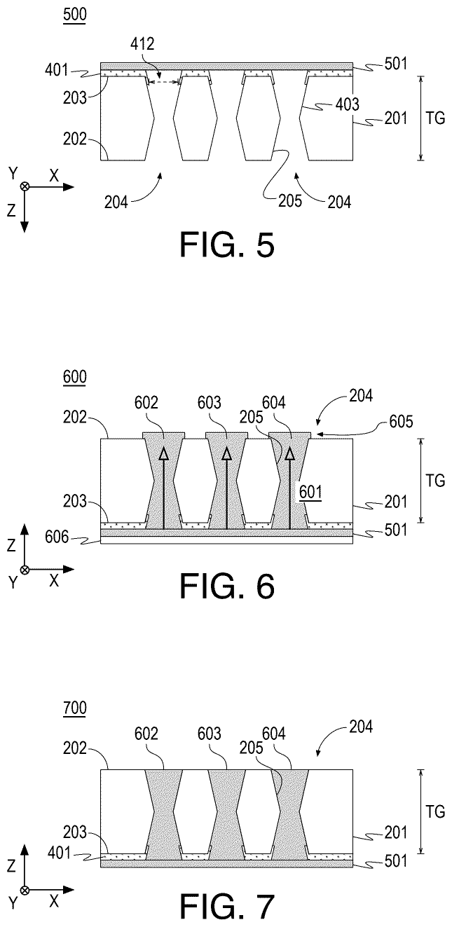

FIG. 5 is an illustration of a cross-sectional side view of a glass substrate structure 500 similar to glass substrate structure 400 after removal of backing film or material layer 301 and attachment of metal foil 501. Metal foil 501 may be any suitable material or multi-layer material stack that provides for a seed for bottom-up via metallization plating. In some embodiments, metal foil 501 is a copper metal foil. However, other material systems may be used. As shown, portions of metal foil 501 are exposed within at least portions 412 of openings 204. It is also noted that portions 403 of sidewalls 205 of openings 204 are also exposed such that, advantageously, no seed material is tightly bound to portions 403 of sidewalls 205. Thereby, stress is reduced by the via metallizations formed herein below. As discussed, a cure or anneal operation may be administered before or after metal foil 501 attachment depending on the material selected for adhesive material 401.

Returning to FIG. 1, methods 100 continue at operation 105, where a non-plating film is applied to the metal foil, and a suitable metal is plated in a bottom-up manner from the metal foil applied at operation 104 to fill the openings. Notably, the non-plating film restricts current supply for bottom-up plating rather than plating from the metal foil on the surface. In some embodiments, the plating is copper plating starting from a copper foil applied at the bottom of the opening. In some embodiments, the plating will plate through the opening in a bottom-up fashion until over plating is evident on the top side. The resultant plated material has a consistent microstructure and morphology throughout. Notably, no seed material is evident at the sidewall of the plated opening (i.e., no other seed material nor different microstructure and morphology). Furthermore, one or more air gaps may exist between the plated metal and the sidewall of the opening as the bottom-up plating progresses without a seed layer on the opening sidewall. In some embodiments, no air gaps are evident, however, even in such contexts, the via metallization is absent a seed layer and therefore there is no direct seed layer coupling to the glass substrate.

FIG. 6 is an illustration of a cross-sectional side view of a glass substrate structure 600 similar to glass substrate structure 500, after application of non-plating film 606, and during and after bottom-up plating 601 of via metallizations 602, 603, 604 within openings 204. As discussed, bottom-up plating 601 progresses up from metal foil 501 to fill openings 204 until an overburden 605 of via metallizations 602, 603, 604 is evident. Via metallizations 602, 603, 604 may be any suitable material such as substantially pure or pure copper. Resultant via metallizations 602, 603, 604 or metallization structures may be characterized as through substrate vias (TSVs) or through glass vias (TGVs). As discussed, non-plating film 606 restricts plating from the surface of metal foil 501 opposite openings 204.

Returning to FIG. 1, methods 100 continue at operation 106, where the overburden due to bottom-up plating may be removed as needed, and the non-plating film applied at operation 105 is removed. For example, the plated via metallization may be planarized or polished to remove overburden associated with the plating process and/or to provide a planar surface for continues processing. Furthermore, the non-plating film may be removed using any suitable technique or techniques such as UV release, peeling, or the like.

FIG. 7 is an illustration of a cross-sectional side view of a glass substrate structure 700 similar to glass substrate structure 600 after planarization processing to form via metallizations 602, 603, 604 that have surfaces adjacent first surface 202 that are substantially planar with first surface 202, and after removal of non-plating film 606. As shown, following planarization, via metallizations 602, 603, 604 remain only adjacent to sidewalls 205 of openings 204 at first surface 202.

Returning to FIG. 1, methods 100 continue at operation 107, where a protective film is laminated or otherwise attached to the surface of the glass substrate planarized at operation 106. The protective film may have any suitable composition and may be of any suitable thickness and rigidity such that the protective film protects the surface during subsequent processing. The protective film may be attached to the glass substrate using any suitable technique or techniques such as a removable adhesive, a releasable tape, or the like. In some embodiments, the protective film is a UV-releasable protective film attached to the polished side or surface of the glass substrate.

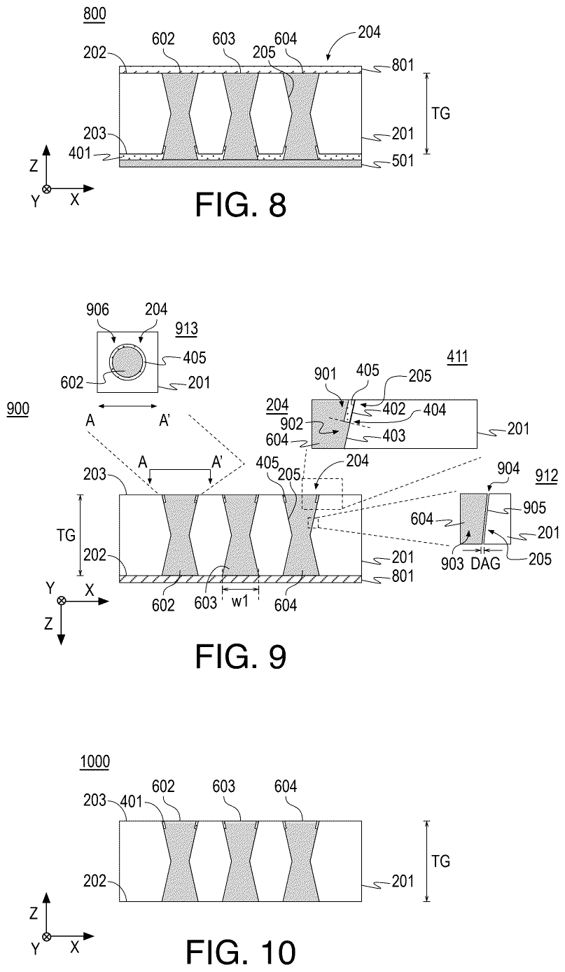

FIG. 8 is an illustration of a cross-sectional side view of a glass substrate structure 800 similar to glass substrate structure 800 after attaching a protective film or material layer 801 that substantially covers first surface 202 and protects first surface 202 including surfaces of via metallizations 602, 603, 604. Material layer 801 may be any material that provides protection and mechanical support during subsequent metal foil and/or etch processing discussed herein below. In some embodiments, material layer 801 is a polymer material. Material layer 801 may be attached to first surface 202 using any suitable technique or techniques such as lamination techniques. In some embodiments, material layer 801 is a UV-releasable layer such as a UV releasable film.

Returning to FIG. 1, methods 100 continue at operation 108, where the metal foil applied at operation 104 is removed and a portion of the adhesive applied at operation 103 is optionally removed. The metal foil may be removed using any suitable technique or techniques such as a bulk metal etch process. In some embodiments, the metal foil is copper, and the removal includes a bulk copper wet etch to remove the foil. At least portions of the adhesive material layer may then be removed using any suitable technique or techniques. In some embodiments, portions of the adhesive material layer are removed using polish techniques, dry etch techniques, or wet etch techniques. For example, a polish step may advantageously planarize the adhesive with the via metallization plated within the opening.

FIG. 9 is an illustration of a cross-sectional side view of a glass substrate structure 900 similar to glass substrate structure 800 after removing metal foil 501 and removal of portions of adhesive material 401. As discussed, metal foil 501 may be removed using wet etch techniques and portions of adhesive material 401 may be removed using dry and/or wet techniques while other components of the glass substrate structure 900 are protected by material layer 801.

As shown, glass substrate structure 900 includes glass substrate 201 having thickness TG extending between first surface 202 and second surface 203, opening 204 extending from first surface 202 through the thickness TG of glass substrate 201 to second surface 203 such that opening 204 defines sidewall 205 of glass substrate 201 within opening 204, extension 405 of polymeric or adhesive material 401 on portion 402 of sidewall 205 within opening 204, and via metallizations 602, 603, 604 within opening 204 and extending from first surface 202 through thickness TG of glass substrate 201 to second surface 203 such that via metallizations 602, 603, 604 have a portion 901 directly on extension 405 within opening 204 and a portion 902 directly on portion 403 of sidewall 205 of glass substrate 201 within opening 204.

As discussed, due to the bottom-up fabrication of via metallizations 602, 603, 604, via metallizations 602, 603, 604 are not rigidly attached to sidewall 205 of glass substrate 201 and, in subsequent thermal processing the CTE mismatch between via metallizations 602, 603, 604 and glass substrate 201 does not cause cracking and other failures due to the mechanical decoupling of via metallizations and glass substrate 201. As shown in enlarged view 912, in some embodiments, glass substrate structure 900 includes one or more air gaps 904 between a portion 903 of via metallizations 602, 603, 604 and a portion 905 of sidewall 205 of glass substrate 201. As discussed, air gap 904 may be filled with any pertinent ambient gas, in accordance with its use in the art. Air gap 904 may be characterized as a gap, void, span, or the like.

Air gap 904 may have any suitable distance DAG (distance air gap) between portion 903 of via metallizations 602, 603, 604 and portion 905 of sidewall 205. In some embodiments, the distance DAG between portion 903 of via metallizations 602, 603, 604 and portion 905 of sidewall 205 is not less than 10 nm and not more than 100 nm. In some embodiments, the distance DAG between portion 903 of via metallizations 602, 603, 604 and portion 905 of sidewall 205 is not less than 20 nm and not more than 75 nm. In some embodiments, the distance DAG between portion 903 of via metallizations 602, 603, 604 and portion 905 of sidewall 205 is not less than 25 nm and not more than 50 nm. In some embodiments, the distance DAG between portion 903 of via metallizations 602, 603, 604 and portion 905 of sidewall 205 is not less than 30 nm. Other distances may be used. Furthermore, air gaps 904 may be distributed in any manner through via metallizations 602, 603, 604. In some embodiments, portions of via metallizations 602, 603, 604 are directly on (i.e., in physical contact with) sidewalls 205 at some positions whereas air gaps 904 are at other positions. In some embodiments, the percentage of air gap 904 area to total area within openings 204 is not less than 50%. In some embodiments, the percentage of air gap 904 area to total area within openings 204 is not less than 75%. Other air gap fractions may be used.

As discussed, due to the bottom-up plating of via metallizations 602, 603, 604, an entirety of each of via metallizations 602, 603, 604 are the same material and have the same characteristics. The same material and characteristics include material composition, microstructure, and morphology and extend throughout openings 204. In some embodiments, via metallizations 602, 603, 604 are each substantially pure copper. In some embodiments, via metallizations 602, 603, 604 are each pure copper. Notably, the entirety of metallizations 602, 603, 604 includes portions 901, 902, 903 of via metallizations 602, 603, 604 such that those portions are the same composition and have the same characteristics. In some embodiments, the entirety of via metallizations 602, 603, 604 are substantially pure copper having a shared or constant microstructure as discussed above.

As shown in enlarged view 913, the polymeric material of extension 405 extends fully around an inner cross-sectional shape 906 of openings 204 at second surface 203. That is, extension 405 is adjacent to a rim of glass substrate 201 defining inner cross-sectional shape 906. Inner cross-sectional shape 906 may be any suitable shape such as circular (as shown), oval, or the like. In some embodiments, a top surface of extension 405, a top surface of via metallizations 602, 603, 604, and a top surface of glass substrate define a planar surface as indicated by second surface 203.

Returning to FIG. 1, methods 100 continue at operation 109, where the protective film applied at operation 107 is removed and the workpiece is optionally cleaned in preparation for continued processing. The protective film may be removed using any suitable technique or techniques such as UV release, peeling, heat treatment, or the like. The surface may be optionally cleaned after protective film removal.

FIG. 10 is an illustration of a cross-sectional side view of a glass substrate structure 1000 similar to glass substrate structure 900 after removal of protective film or material layer 801. As discussed, material layer 801 may be removed using any suitable technique or techniques such as UV release, peeling, heat treatment, or the like, and glass substrate structure 1000 may be cleaned using any suitable technique or techniques prior to continued processing as discussed below with respect to operation 110 and FIGS. 13-15.

As discussed, in some embodiments, at least portions (i.e., extensions 405) of adhesive material 401 remain. In some embodiments, the entirety or majority of adhesive material 401 as applied at operation 102 remains after copper foil removal. With reference to glass substrate structure 800 of FIG. 8, metal foil 501 may be removed while all or most of adhesive material 401 remains.

FIG. 11 is an illustration of a cross-sectional side view of a glass substrate structure 1100 similar to glass substrate structure 800 after removing metal foil 501 using any suitable technique or techniques such as wet etch techniques. In the context of glass substrate structure 1100, as shown with respect to enlarged view 1111 and enlarged view 1113, in some embodiments, glass substrate structure 900 includes top surface portion 406 and extension 405 of adhesive material 401. Such components may have any characteristics discussed elsewhere herein. For example, in the context of FIG. 11, the polymeric material includes extension 405, which extends fully around inner cross-sectional shape 906 of openings 204 at second surface 203, and the polymeric material includes top surface portion 406, which extends across second surface 203 Extension 405 is adjacent to a rim of glass substrate 201 defining inner cross-sectional shape 906 and top surface portion extends from extension 405 across second surface 203 and into adjacent ones of openings 204.

As shown in FIG. 11, adhesive material 401 thereby includes extensions 1101, 1103 and top surface portion 1102 such that extensions 1101, 1103 and top surface portion 1102 are parts of a continuous material having substantially the same composition and characteristics. As shown, extension 1101 is between a portion of via metallization 602 and a first opening 204 and extension 1103 is between a portion of via metallization 603 and a second opening 204. Top surface portion 1102 extends between extensions 1101, 1103 and over second surface 203 of glass substrate 201.

FIG. 12 is an illustration of a cross-sectional side view of a glass substrate structure 1200 similar to glass substrate structure 1100 after removal of protective film or material layer 801. Material layer 801 may be removed using any suitable technique or techniques such as UV release, peeling, heat treatment, or the like, and glass substrate structure 1200 may be cleaned using any suitable technique or techniques prior to continued processing as discussed below.

Returning to FIG. 1, methods 100 continue at operation 110, where an electrical routing structure may be built up over at least one side of the glass substrate prior to assembly with an integrated die. The electrical routing structure may be electrically coupled to the through glass vias and may, for example, include one or more levels of metallization features embedded within any suitable dielectric material. The electrical routing structure formed at operation 110 may interconnect one or more IC die to each other and/or couple one or more of IC die to the conductive through vias. Accordingly, the metallization feature pitch of the routing structure is advantageously minimized for highest interconnect density.

FIG. 13 is an illustration of a cross-sectional side view of a package structure 1300 similar to glass substrate structure 1000 after attachment of glass substrate structure 1000 to a handle or carrier 1301 and fabrication or attachment of routing structure 1302. Although illustrated with respect to incorporation of glass substrate structure 1000 into package structures 1300, 1400, 1500, any glass substrate structure discussed herein such as glass substrate structure 1200 may be deployed in package structures 1300, 1400, 1500. Carrier 1301 may have any suitable composition and may be of any suitable thickness. Furthermore, glass substrate structure 1000 may be attached to carrier 1301 using any suitable technique or techniques such as a removable adhesive, a releasable tape, or the like.

In some embodiments, routing structure 1302 is built-up over second surface 203. In some embodiments, routing structure 1302 is built-up over first surface 202 or a routing structure is built-up over first surface 202 and second surface 203. As shown, routing structure 1302 includes one or more levels of redistribution layer (RDL) metallization features 1303 embedded within one or more layers of dielectric material 1304. RDL metallization features 1303 may include any suitable metal such as copper. In some embodiments, a portion of RDL metallization features 1303 are to electrically bridge together two or more IC dies, preferably with a fine metallization feature pitch as enabled by the improved flatness profile of glass substrate 201 as compared to traditional organic preform cores. Furthermore, a portion of routing structure 1302 further includes metallization features 1303 that are to interconnect IC dies to conductive through glass vias 602, 603, 604.

Dielectric material 1304 may be any suitable material or materials such as a molding compound, a spin-on material, or a dry film laminate material. In some embodiments, dielectric material 1304 is applied in a wet or uncured state into a cast and is then dried or cured. Alternatively, dielectric material 1304 may be applied as a semi-cured dry film that is fully cured following its application to glass substrate 201. The composition of dielectric material 1304 may include one or more of an organic dielectric material, such as, an epoxy resin, phenolic-glass, or a resinous film such as the GX-series films commercially available from Ajinomoto Fine-Techno Co., Inc. (ABF). Exemplary epoxy resins for deployment in dielectric material 1304 include an acrylate of novolac such as epoxy phenol novolacs (EPN) or epoxy cresol novolacs (ECN). In some embodiments, dielectric material 1304 is a bisphenol-A epoxy resin including epichlorohydrin, for example. In some embodiments, dielectric material 1304 includes an aliphatic epoxy resin.

Returning to FIG. 1, methods 100 continue at operation 111, where at least one IC die is assembled to the workpiece. In some embodiments, the one or more IC dies are attached to the electrical routing structure formed at operation 110. The one or more IC dies assembled at operation 111 may each include any electrical circuitry. In some embodiments, one or more of the IC dies include logic circuitry including logic gates. The one or more IC dies assembled at operation 111 may also include any photonic circuitry suitable for the detection, emission or processing (e.g., filtering, multiplexing and demultiplexing) of optical signals.

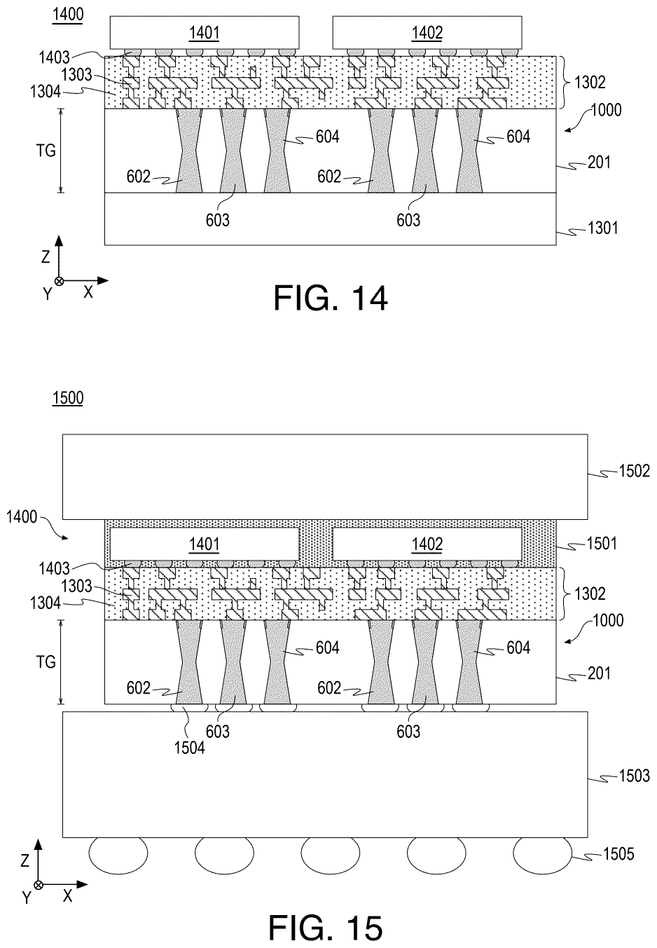

FIG. 14 is an illustration of a cross-sectional side view of a package structure 1400 similar to package structure 1300 after attachment of any number of IC dies such as IC dies 1401, 1402 to routing structure 1302 using intervening electrical interconnects 1403. As shown, IC dies 1401, 1402 are assembled to interconnect interfaces within a top metallization level of routing structure 1302 of an assembled package structure 1400. Although illustrated with two IC dies 1401, 1402, package structure 1400 may include any number of IC dies. In some embodiments, IC dies 1401, 1402 are the first level of dies of a packaged multi-die IC device package structure. IC dies 1401, 1402 may be directly bonded to routing structure 1302, or, electrically coupled through intervening electrical interconnects 1403, which may include solder of any suitable composition. In the example illustrated, IC dies 1401, 1402 are each flip-chip attached with integrated circuitry within each die being proximal to a top surface of routing structure 1302. In alternative embodiments, IC dies 1401, 1402 include through die vias (not shown) with integrated circuity being distal from the top surface of routing structure 1302.

IC dies 1401, 1402 may include any suitable circuitry. In some embodiments, at least one of IC dies 1401, 1402 is a fully functional ASIC. In some embodiments, IC dies 1401, 1402 include a chiplet or tile that has more limited functionality supplementing the function of one or more others of IC dies 1401, 1402 that are to be part of the same multi-die device. A chiplet or tile may, for example, be any of a wireless radio circuit, microprocessor core, electronic memory circuit, floating point gate array (FPGA), power management and/or power supply circuit, or a MEMS device. In some examples, one or more of IC dies 1401, 1402 includes one or more banks of active repeater circuitry to improve multi-die interconnects (e.g., network-on-chip architectures). In other examples, one or more of IC dies 1401, 1402 includes clock generator circuitry or temperature sensing circuitry. In other examples, one or more of IC dies 1401, 1402 includes logic circuitry that, along with other IC dies 1401, 1402 implement multi-chiplet aggregated logic circuitry (e.g., mesh network-on-chip architectures). In some specific examples, at least one of IC dies 1401, 1402 includes microprocessor core circuitry, for example including one or more shift registers. IC dies 1401, 1402 may include field effect transistors (FETs) with a device pitch of 80 nm, or less. The FETs may be of any architecture (e.g., planar, non-planar, single-gate, multi-gate, stacked nanosheet, etc.). Additionally or in the alternative, IC dies 1401, 1402 may include active devices other than FETs such as magnetic tunnel junctions (MTJs), capacitors, or the like. In some embodiments, IC dies 1401, 1402 include one or more IC die metallization levels embedded within an insulator.

Returning to FIG. 1, methods 100 continue at operation 112, where the final device is packaged, assembled, and output, for example, by attachment of a package to a host component. The assembly or package may be installed in any suitable electronic device such as a laptop, a netbook, a notebook, an ultrabook, a smartphone, a tablet, a personal digital assistant PDA, an ultra-mobile PC, a mobile phone, a desktop computer, a server, a printer, a scanner, a monitor, a set-top box, an entertainment control unit, a digital camera, a portable music player, a digital video recorder, or the like.

FIG. 15 is an illustration of a cross-sectional side view of a package structure 1500 similar to package structure 1400 after attachment to a host component 1503 and deployment of one or more heat spreaders and/or heat sinks 1502. As shown, package structure 1500, which may be characterized as a system, includes package structure 1400 attached to host component 1503 with interconnects 1504. In some embodiments, interconnects 1504 are solder (e.g., SAC) microbumps although other interconnect features may be used. In some embodiments, host component 1503 is predominantly silicon. Host component 1503 may also include one or more alternative materials known to be suitable as interposers or package substrates (e.g., an epoxy preform, cored or coreless laminate board, etc.). In some embodiments, host component 1503 is a printed circuit board (PCB). In some embodiments, host component 1503 includes one or more metallized redistribution levels (not depicted) embedded within a dielectric material. Host component 1503 may also include one or more IC dies, one or more passive or active components, or the like embedded therein.

Host component 1503 may include interconnects 1505 which may include solder (e.g., ball, bump, etc.) suitable for a given host board architecture (e.g., surface mount FR4, etc.). Also as shown, one or more heat spreaders and/or heat sinks 1502 may be coupled to package structure 1400, which may be advantageous, for example, where IC dies 1401, 1402 include one or more CPU cores or other circuitry of similar power density. Any package dielectric 1501, such as a mold material, may surround sidewalls of IC dies 1401, 1402. Although not illustrated, package dielectric 1501 may be ground down to a top surface of IC dies 1401, 1402 such that heat spreader/sink 1502 may be in closer contact with IC dies 1401, 1402.

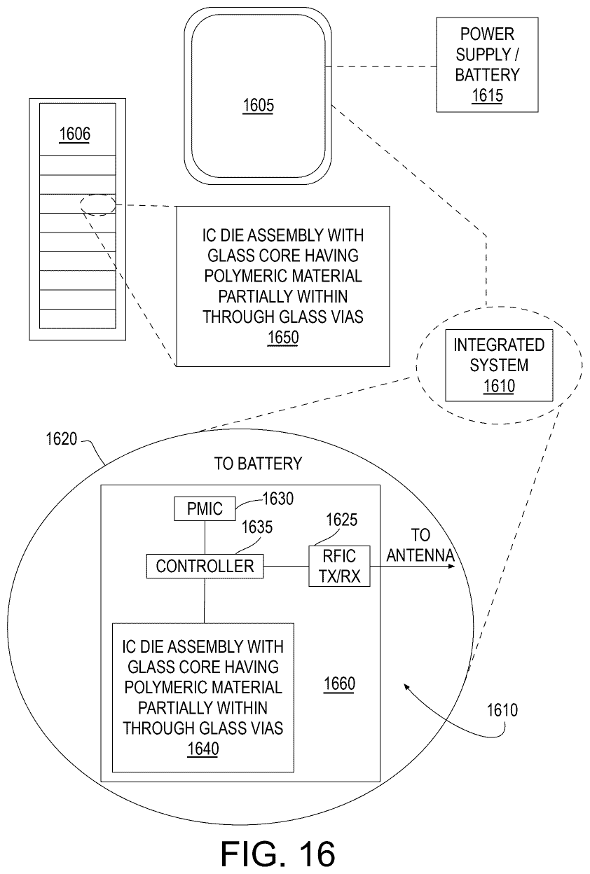

FIG. 16 illustrates exemplary systems employing an IC assembly including a glass core substrate with bottom-up plated through glass vias, arranged in accordance with at least some implementations of the present disclosure. The system may be a mobile computing platform 1605 and/or a data server machine 1606, for example. Either may employ a component assembly including an IC assembly including a glass core substrate with bottom-up plated through glass vias as described elsewhere herein. Server machine 1606 may be any commercial server, for example including any number of high-performance computing platforms disposed within a rack and networked together for electronic data processing, which in the exemplary embodiment includes an IC die assembly 1650 with a glass core substrate with bottom-up plated through glass vias as described elsewhere herein. Mobile computing platform 1605 may be any portable device configured for each of electronic data display, electronic data processing, wireless electronic data transmission, or the like. For example, mobile computing platform 1605 may be any of a tablet, a smart phone, a laptop computer, etc., and may include a display screen (e.g., a capacitive, inductive, resistive, or optical touchscreen), a chip-level or package-level integrated system 1610, and a battery 1615 and/or power supply circuitry. Although illustrated with respect to mobile computing platform 1605, in other examples, chip-level or package-level integrated system 1610 and battery 1615 may be implemented in a desktop computing platform, an automotive computing platform, an internet of things platform, or the like. As discussed below, in some examples, the disclosed systems may include a sub-system 1660 such as a system on a chip (SOC) or an integrated system of multiple ICs, which is illustrated with respect to mobile computing platform 1605.

Whether disposed within integrated system 1610 illustrated in expanded view 1620 or as a stand-alone packaged device within data server machine 1606, sub-system 1660 may include memory circuitry and/or processor circuitry 1640 (e.g., RAM, a microprocessor, a multi-core microprocessor, graphics processor, etc.), a power management integrated circuit (PMIC) 1630, a controller 1635, and a radio frequency integrated circuit (RFIC) 1625 (e.g., including a wideband RF transmitter and/or receiver (TX/RX)). As shown, one or more IC dies, such as memory circuitry and/or processor circuitry 1640 may be assembled and implemented such that one or more have an IC assembly including a glass core substrate with bottom-up plated through glass vias as described herein. In some embodiments, RFIC 1625 includes a digital baseband and an analog front-end module further including a power amplifier on a transmit path and a low noise amplifier on a receive path. Functionally, PMIC 1630 may perform battery power regulation, DC-to-DC conversion, etc., and so has an input coupled to battery 1615, and an output providing a current supply to other functional modules. As further illustrated in FIG. 16, in the exemplary embodiment, RFIC 1625 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 1640 may provide memory functionality for sub-system 1660, high level control, data processing and the like for sub-system 1660. In alternative implementations, each of the SOC modules may be integrated onto separate ICs coupled to a package substrate, interposer, or board.

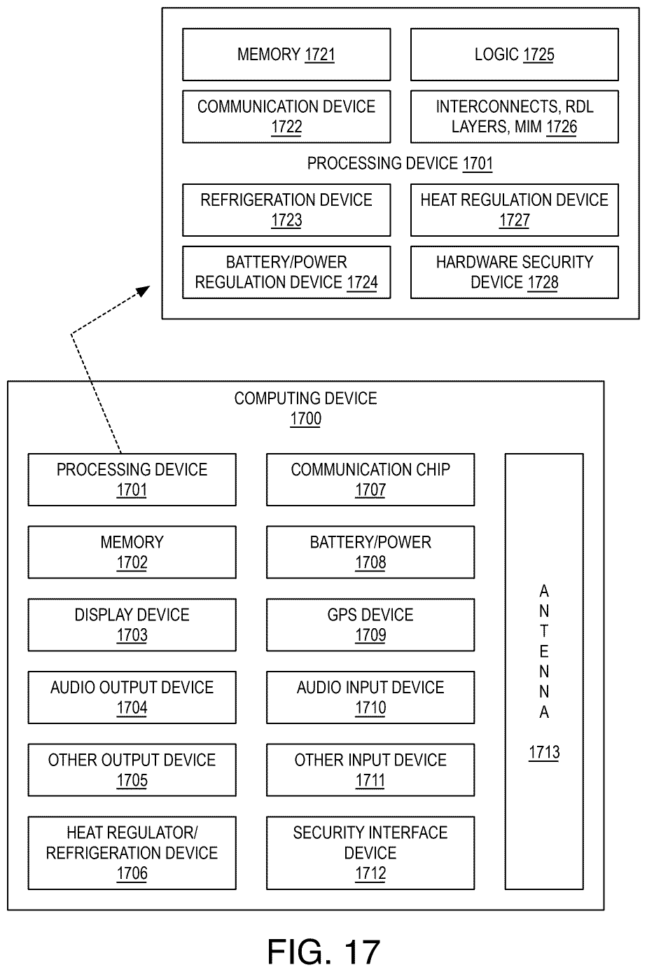

FIG. 17 is a block diagram of a computing device 1700, in accordance with some embodiments. For example, one or more components of computing device 1700 may include any of the package structures or assemblies having a glass core substrate with bottom-up plated through glass vias as discussed elsewhere herein. A number of components are illustrated in FIG. 17, but any one or more of these components may be omitted or duplicated, as suitable for the application. In some embodiments, some of the components included in computing device 1700 may be attached to one or more printed circuit boards (e.g., a motherboard). In some embodiments, various ones of these components may be fabricated onto a single system-on-a-chip (SoC) die or implemented with a disintegrated plurality of chiplets or tiles packaged together. Any of such packaged components may include a vertically aligned photonics via implemented in an assembly having disaggregated PIC functionality, for example, as discussed herein. Additionally, in various embodiments, computing device 1700 may not include one or more of the components illustrated in FIG. 17, but computing device 1700 may include interface circuitry for coupling to the one or more components. For example, computing device 1700 may not include a display device 1703, but may include display device interface circuitry (e.g., a connector and driver circuitry) to which display device 1703 may be coupled.

Computing device 1700 may include a processing device 1701 (e.g., one or more processing devices). As used herein, the term processing device or processor indicates a device that processes electronic data from registers and/or memory to transform that electronic data into other electronic data that may be stored in registers and/or memory. Processing device 1701 may include a memory 1721, a communication device 1722, a refrigeration/active cooling device 1723, a battery/power regulation device 1724, logic 1725, interconnects 1726, a heat regulation device 1727, and a hardware security device 1728.

Processing device 1701 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable compute units.

Processing device 1701 may include a memory 1702, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, processing device 1701 shares a package with memory 1702. This memory may be used as cache memory and may include embedded dynamic random-access memory (eDRAM) or spin transfer torque magnetic random-access memory (STT-M RAM).

Computing device 1700 may include a heat regulation/refrigeration device 1706. Heat regulation/refrigeration device 1706 may maintain processing device 1701 (and/or other components of computing device 1700) at a predetermined low temperature during operation. This predetermined low temperature may be any temperature discussed elsewhere herein.

In some embodiments, computing device 1700 may include a communication chip 1707 (e.g., one or more communication chips). For example, the communication chip 1707 may be configured for managing wireless communications for the transfer of data to and from computing device 1700. The term “wireless” and its derivatives may be used to describe circuits, devices, systems, methods, techniques, communications channels, etc., that may communicate data through the use of modulated electromagnetic radiation through a nonsolid medium.

Computing device 1700 may include any photonics structure discussed herein that may facilitate communication between one or more instances of processing device 1701 and/or one or more instances of memory 1702, for example.

Computing device 1700 may include battery/power circuitry 1708. Battery/power circuitry 1708 may include one or more energy storage devices (e.g., batteries or capacitors) and/or circuitry for coupling components of computing device 1700 to an energy source separate from computing device 1700 (e.g., AC line power).

Computing device 1700 may include a display device 1703 (or corresponding interface circuitry, as discussed above). Display device 1703 may include any visual indicators, such as a heads-up display, a computer monitor, a projector, a touchscreen display, a liquid crystal display (LCD), a light-emitting diode display, or a flat panel display, for example.

Computing device 1700 may include an audio output device 1704 (or corresponding interface circuitry, as discussed above). Audio output device 1704 may include any device that generates an audible indicator, such as speakers, headsets, or earbuds, for example.

Computing device 1700 may include an audio input device 1710 (or corresponding interface circuitry, as discussed above). Audio input device 1710 may include any device that generates a signal representative of a sound, such as microphones, microphone arrays, or digital instruments (e.g., instruments having a musical instrument digital interface (MIDI) output).

Computing device 1700 may include a global positioning system (GPS) device 1709 (or corresponding interface circuitry, as discussed above). GPS device 1709 may be in communication with a satellite-based system and may receive a location of computing device 1700, as known in the art.

Computing device 1700 may include another output device 1705 (or corresponding interface circuitry, as discussed above). Examples include an audio codec, a video codec, a printer, a wired or wireless transmitter for providing information to other devices, or an additional storage device.

Computing device 1700 may include another input device 1711 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1700 may include a security interface device 1712. Security interface device 1712 may include any device that provides security measures for computing device 1700 such as intrusion detection, biometric validation, security encode or decode, managing access lists, malware detection, or spyware detection.

Computing device 1700 may include an antenna 1713. Antenna 1713 may include any device that translates electrical current to radio waves and/or translates radio waves to electrical current.

Computing device 1700, or a subset of its components, may have any appropriate form factor, such as a server or other networked computing component, a mobile device, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following pertain to exemplary embodiments.

In one or more first embodiments, an apparatus comprises a glass substrate having a thickness extending between a first surface and an opposing second surface thereof, an opening extending from the first surface through the thickness of the glass substrate to the second surface, the opening defining a sidewall of the glass substrate within the opening, a polymeric material on a first portion of the sidewall within the opening immediately adjacent the first surface, and a via metallization within the opening and extending from the first surface through the thickness of the glass substrate to the second surface, the via metallization having a first portion directly on the polymeric material within the opening and a second portion directly on a second portion of the sidewall of the glass substrate within the opening.

In one or more second embodiments, further to the first embodiments, the apparatus further comprises an air gap between a third portion of the via metallization and a third portion of the sidewall of the glass substrate within the opening.

In one or more third embodiments, further to the first or second embodiments, the air gap extends across a distance of not less than 30 nm between the third portion of the via metallization and the third portion of the sidewall of the glass substrate orthogonal to the third portion of the sidewall of the glass substrate.

In one or more fourth embodiments, further to the first through third embodiments, an entirety of the via metallization comprises the first portion, the second portion, and the third portion, and the entirety of the via metallization is substantially pure copper having a shared microstructure.

In one or more fifth embodiments, further to the first through fourth embodiments, the polymeric material comprises one of an epoxy material, a polyimide material, a benzocyclobutene based material, a polyethylene terephthalate based material, or a polyethylene based material.

In one or more sixth embodiments, further to the first through fifth embodiments, the polymeric material has a thickness orthogonal to the first portion of sidewall of not less than 0.5 μm and the polymeric material has a length along the first portion of sidewall of not less than 10 μm.

In one or more seventh embodiments, further to the first through sixth embodiments, the via metallization has an aspect ratio defined by the thickness of the glass substrate over a cross-sectional width of the via metallization at the first surface of not less than 10.

In one or more eighth embodiments, further to the first through seventh embodiments, the polymeric material extends fully around an inner cross-sectional shape of the opening at the first surface and extends across a portion of the first surface to contact a second via metallization within a second opening extending from the first surface through the thickness of the glass substrate to the second surface.

In one or more ninth embodiments, further to the first through eighth embodiments, the apparatus further comprises an integrated circuit (IC) die over the first surface or the second surface of the glass substrate, such that the IC is electrically coupled to the via metallization and the glass substrate is a layer of glass having a thickness of not less than 50 μm, a first length of not less than 10 mm and a second length orthogonal to the first length of not less than 10 mm.

In one or more tenth embodiments, a system comprises a package substrate according to any of the apparatuses of the first through eighth embodiments, the system further comprising an IC die and/or a power supply coupled to the glass substrate.

In one or more eleventh embodiments, an apparatus comprises a glass substrate having an opening extending from a first surface to an opposing second surface thereof, a via metallization within the opening and extending from the first surface to the second surface, and a polymeric material between a first portion of the via metallization and a first portion of a sidewall of the glass substrate defined by the opening, such that the first portion of a sidewall extends from the first surface to a first depth of the opening, and such that a second portion the via metallization is immediately adjacent to a second portion of the sidewall extending from the first depth to the second surface.

In one or more twelfth embodiments, further to the eleventh embodiments, the apparatus further comprises an air gap between the via metallization and the second portion of the sidewall.

In one or more thirteenth embodiments, further to the eleventh or twelfth embodiments, an entirety of the via metallization comprises the first portion and the second portion, and the entirety of the via metallization is substantially pure copper having a shared microstructure.

In one or more fourteenth embodiments, further to the eleventh through thirteenth embodiments, the polymeric material has a thickness orthogonal to the first portion of sidewall of not less than 0.5 μm, such that the polymeric material has a length along the first portion of sidewall of not less than 10 μm, and such that the via metallization has an aspect ratio defined by a length of the via metallization orthogonal to the first surface over a cross-sectional width of the via metallization at the first surface of not less than 10.

In one or more fifteenth embodiments, further to the eleventh through fourteenth embodiments, the polymeric material extends fully around an inner cross-sectional shape of the opening at the first surface and extends across a portion of the first surface to contact a second via metallization within a second opening extending from the first surface to the second surface.

In one or more sixteenth embodiments, further to the eleventh through fifteenth embodiments, the apparatus further comprises an integrated circuit (IC) die over the first surface or the second surface of the glass substrate, such that the IC is electrically coupled to the via metallization and the glass substrate is a layer of glass having a thickness of not less than 50 μm, a first length of not less than 10 mm and a second length orthogonal to the first length of not less than 10 mm.

In one or more seventeenth embodiments, a system comprises a package substrate according to any of the apparatuses of eleventh through fifteenth embodiments, the system further comprising an IC die and/or a power supply coupled to the glass substrate.

In one or more eighteenth embodiments, a method comprises depositing an adhesive material over a first surface of a glass substrate, the glass substrate comprising a plurality of openings extending from the first surface to an opposing second surface of the glass substrate, such that application of the adhesive material leaves at least a portion of each of the openings exposed, applying a metal foil to the adhesive material over the first surface, and plating a metal within each of the openings beginning from the metal foil at the first surface and extending to the second surface to form a via metallization within the opening.

In one or more nineteenth embodiments, further to the eighteenth embodiments, depositing the adhesive material comprises a slit coating of one of an epoxy material, a polyimide material, a benzocyclobutene based material, a polyethylene terephthalate based material, or a polyethylene based material.

In one or more twentieth embodiments, further to the eighteenth or nineteenth embodiments, the adhesive material is deposited on the first surface of the glass substrate at a thickness of not more than 10 μm.

In one or more twenty-first embodiments, further to the eighteenth through twentieth embodiments, depositing the adhesive material comprises attaching the second surface of the glass substrate to a material layer and pulling a vacuum on the first surface while depositing the adhesive material.

In one or more twenty-second embodiments, further to the eighteenth through twenty-first embodiments, the method further comprises removing at least a portion of the adhesive material by attaching the second surface of the glass substrate to a material layer, etching the adhesive material, and releasing the material layer.

It will be recognized that the invention is not limited to the embodiments so described, but can be practiced with modification and alteration without departing from the scope of the appended claims. For example, the above embodiments may include specific combination of features. However, the above embodiments are not limited in this regard and, in various implementations, the above embodiments may include undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
a glass substrate having a thickness extending between a first surface and an opposing second surface thereof;
an opening extending from the first surface through the thickness of the glass substrate to the second surface, the opening defining a sidewall of the glass substrate within the opening;
a polymeric material on a first portion of the sidewall within the opening immediately adjacent the first surface; and
a via metallization within the opening and extending from the first surface through the thickness of the glass substrate to the second surface, the via metallization having a first portion directly on the polymeric material within the opening and a second portion directly on a second portion of the sidewall of the glass substrate within the opening.

2. The apparatus of claim 1, further comprising an air gap between a third portion of the via metallization and a third portion of the sidewall of the glass substrate within the opening.

3. The apparatus of claim 2, wherein the air gap extends across a distance of not less than 30 nm between the third portion of the via metallization and the third portion of the sidewall of the glass substrate orthogonal to the third portion of the sidewall of the glass substrate.

4. The apparatus of claim 2, wherein an entirety of the via metallization comprises the first portion, the second portion, and the third portion, and wherein the entirety of the via metallization is substantially pure copper having a shared microstructure.

5. The apparatus of claim 1, wherein the polymeric material comprises one of an epoxy material, a polyimide material, a benzocyclobutene based material, a polyethylene terephthalate based material, or a polyethylene based material.

6. The apparatus of claim 1, wherein the polymeric material has a thickness orthogonal to the first portion of sidewall of not less than 0.5 μm and wherein the polymeric material has a length along the first portion of sidewall of not less than 10 μm.

7. The apparatus of claim 1, wherein the via metallization has an aspect ratio defined by the thickness of the glass substrate over a cross-sectional width of the via metallization at the first surface of not less than 10.

8. The apparatus of claim 1, wherein the polymeric material extends fully around an inner cross-sectional shape of the opening at the first surface and extends across a portion of the first surface to contact a second via metallization within a second opening extending from the first surface through the thickness of the glass substrate to the second surface.

9. The apparatus of claim 1, further comprising:
an integrated circuit (IC) die over the first surface or the second surface of the glass substrate, wherein the IC is electrically coupled to the via metallization and the glass substrate is a layer of glass having a thickness of not less than 50 μm, a first length of not less than 10 mm and a second length orthogonal to the first length of not less than 10 mm.

10. An apparatus, comprising:
a glass substrate having an opening extending from a first surface to an opposing second surface thereof;
a via metallization within the opening and extending from the first surface to the second surface; and
a polymeric material between a first portion of the via metallization and a first portion of a sidewall of the glass substrate defined by the opening, wherein the first portion of a sidewall extends from the first surface to a first depth of the opening, and wherein a second portion the via metallization is immediately adjacent to a second portion of the sidewall extending from the first depth to the second surface.

11. The apparatus of claim 10, further comprising an air gap between the via metallization and the second portion of the sidewall.

12. The apparatus of claim 10, wherein an entirety of the via metallization comprises the first portion and the second portion, and wherein the entirety of the via metallization is substantially pure copper having a shared microstructure.

13. The apparatus of claim 10, wherein the polymeric material has a thickness orthogonal to the first portion of sidewall of not less than 0.5 μm, wherein the polymeric material has a length along the first portion of sidewall of not less than 10 μm, and wherein the via metallization has an aspect ratio defined by a length of the via metallization orthogonal to the first surface over a cross-sectional width of the via metallization at the first surface of not less than 10.

14. The apparatus of claim 10, wherein the polymeric material extends fully around an inner cross-sectional shape of the opening at the first surface and extends across a portion of the first surface to contact a second via metallization within a second opening extending from the first surface to the second surface.

15. The apparatus of claim 10, further comprising:
an integrated circuit (IC) die over the first surface or the second surface of the glass substrate, wherein the IC is electrically coupled to the via metallization and the glass substrate is a layer of glass having a thickness of not less than 50 μm, a first length of not less than 10 mm and a second length orthogonal to the first length of not less than 10 mm.

16. A method, comprising:
depositing an adhesive material over a first surface of a glass substrate, the glass substrate comprising a plurality of openings extending from the first surface to an opposing second surface of the glass substrate, wherein application of the adhesive material leaves at least a portion of each of the openings exposed;
applying a metal foil to the adhesive material over the first surface; and
plating a metal within each of the openings beginning from the metal foil at the first surface and extending to the second surface to form a via metallization within the opening.

17. The method of claim 16, wherein depositing the adhesive material comprises a slit coating of one of an epoxy material, a polyimide material, a benzocyclobutene based material, a polyethylene terephthalate based material, or a polyethylene based material.

18. The method of claim 16, wherein the adhesive material is deposited on the first surface of the glass substrate at a thickness of not more than 10 μm.

19. The method of claim 16, wherein depositing the adhesive material comprises attaching the second surface of the glass substrate to a material layer and pulling a vacuum on the first surface while depositing the adhesive material.

20. The method of claim 16, further comprising removing at least a portion of the adhesive material by attaching the second surface of the glass substrate to a material layer, etching the adhesive material, and releasing the material layer.
